(19) United States
(12) Patent Application Publication
(10) Pub. No.: US 2026/0126478 A1
(43) Pub. Date: May 7, 2026

(54) DEVICE WITH OPENING DETECTION

(71) Applicant: SAGEMCOM ENERGY & TELECOM SAS, BOIS-COLOMBES (FR)

(72) Inventors: Henri TEBOULLE, BOIS-COLOMBES (FR); Christophe GRINCOURT, BOIS-COLOMBES (FR)

(21) Appl. No.: 19/347,667

(22) Filed: Oct. 1, 2025

(30) Foreign Application Priority Data
Nov. 4, 2024 (FR) 2412057

(51) Int. Cl. G01R 22/06; H02J 7/34; H05K 5/03

(52) U.S. Cl. CPC G01R 22/066; G01R 22/063; H02J 7/345; H05K 5/03; H02J 2207/50

(57) ABSTRACT

Disclosed is a device comprising a housing that comprises components; a cover configured to be positioned on the housing to restrict access to the components when the cover is in the closed position; a capacitor and a fuse, the capacitor and fuse being dimensioned so that the fuse blows when the capacitor discharges through the fuse; a capacitor charging circuit configured to charge the capacitor when the device is powered up; a discharge circuit for discharging the capacitor through the fuse, said discharge circuit comprising a first switch cooperating with a part integral with the cover in order to prevent the discharging of the capacitor when the cover is in the closed position; and to allow the capacitor to discharge through the fuse when the cover is in the open position.

### CROSS-REFERENCE TO RELATED APPLICATIONS

The present application claims priority to French Application No. 2412057 filed with the Intellectual Property Office of France on November 4, 2024, which is incorporated herein by reference in its entirety for all purposes.

### TECHNICAL FIELD

The various embodiments described in the present disclosure relate to a device provided with opening detection. The device can be, but is not limited to, an electric meter.

### PRIOR ART

Consumables meters, such as electricity meters, are vulnerable to tampering for fraudulent purposes. The detection of opening of a meter, once it has been installed in its place of use and activated, is an indication that fraud has been committed – detection of this can lead to the operator in question being called in for verification.

Some known meters offer a function for detecting the opening of the terminal cover and/or main cover, in particular using a battery that continues to power a microcontroller when the meter is no longer being powered. The microcontroller can then continuously monitor the status of a switch linked to the main cover or terminal cover. The battery can also be replaced by a high-value supercapacitor, typically of 1 F, which allows the detection function to be kept active for five to seven days. The components are expensive, however, and some operators prohibit the use of a battery in a meter. In addition, the duration of detection is necessarily time-limited – so it is possible to detach the main cover or terminal cover without risk of detection simply by waiting long enough.

It is also known practice to use a monostable relay with a movable core to detect the opening of a cover closing a meter box. It is likewise known practice to use an incremental encoder that reacts to the opening of the cover. However, such solutions are expensive and can be mechanically complex and in particular, as with the incremental encoder for example, subject to mechanical uncertainties. With this last solution, opening can no longer be detected if the initial value is restored.

A simple solution that allows the opening of a meter housing to be detected, even when it is not being powered, is desirable.

### SUMMARY OF THE INVENTION

A first aspect relates to a device comprising: a housing that comprises components; a cover configured to be positioned on the housing to restrict access to the components when the cover is in a closed position; a capacitor and a fuse, the capacitor and fuse being dimensioned so that the fuse blows when the capacitor discharges through the fuse; a capacitor charging circuit configured to charge the capacitor when the device is powered up; a discharge circuit for discharging the capacitor through the fuse, said discharge circuit comprising a first switch cooperating with a part integral with the cover in order to prevent the discharging of the capacitor when the cover is in the closed position; and allowing the capacitor to discharge through the fuse when the cover is in an open position.

Thus, once the device has been installed and powered up for the first time, the cover cannot be opened undetected, even when the device is no longer powered up, i.e. no longer connected to an external power source. The energy stored by the capacitor is used only to create a current in the fuse, if necessary. This allows the detection function to be kept active for a long time.

According to one or more exemplary embodiments, the discharge circuit is configured to electrically connect the capacitor and the fuse through the first switch, the first switch comprising conductive parts configured to be in electrical contact when the cover is in the open position and to be moved apart by the part integral with the cover when the cover is in the closed position, thereby breaking the electrical contact between the conductive parts.

According to one or more exemplary embodiments, the conductive parts comprise two metal strips.

According to one or more exemplary embodiments, the part integral with the cover is a projecting member integral with the cover.

The security of the device can be increased by positioning or protecting the switch and fuse in such a way as to prevent or at least substantially reduce the possibility of tampering by an unauthorized person who is nonetheless intimately familiar with the operation of the opening detection function.

For example, the switch and fuse can be placed in a compartment of the housing separated by a wall from the portion of the housing made accessible by opening the cover. The switch, however, is arranged so that it can interact with the projecting member of the cover, for example via an opening made in a wall.

Advantageously, the dimensions of the opening are close to those of the cross section of the projecting member. In this way, a malicious third party cannot reach the switch before removing the cover, and has no time to prevent the capacitor from discharging and blowing the fuse when the cover is removed.

Either of these components (switch and fuse) can also be placed under suitable discrete protection. Specific implementation on a printed circuit board can also restrict tampering. In addition, these two components can be chosen so that their inherent structure restricts tampering therewith and, depending on the component, access to the terminals, removal or replacement thereof.

According to one or more exemplary embodiments, the charging circuit comprises a voltage source connected to a first terminal of the capacitor through a resistor, a second terminal of the capacitor being connected to ground, the voltage source being configured to provide a voltage for charging the capacitor when the device is powered up.

According to one or more exemplary embodiments, the capacitor is in a discharged state prior to the first time the device is powered up.

According to one or more exemplary embodiments, the device comprises a second switch controlled by a control signal, the second switch being configured to allow the capacitor to be discharged other than via the fuse.

According to one or more exemplary embodiments, the second switch is configured to short-circuit the capacitor in response to the control signal.

According to one or more exemplary embodiments, the device comprises a processor configured to generate the control signal under the control of an authorized user.

According to one or more exemplary embodiments, the device is an electric meter and the components comprise the electrical terminals of the meter.

According to one or more exemplary embodiments, the device comprises a processor configured to determine whether or not the fuse has blown and, if so, to generate an alert signal.

According to one exemplary embodiment, the fuse is a screen-printed fuse screen-printed on a printed circuit board of the device. This limits the possibility of a blown fuse being replaced by an unauthorized person.

### BRIEF DESCRIPTION OF THE FIGURES

The embodiments will be better understood in light of the following detailed description and the accompanying drawings, which are given by way of illustration only and therefore do not limit the present disclosure.

FIG. 1 is a diagram of a device comprising a removable cover covering the terminals of the meter, according to one embodiment.

FIG. 2 is a diagram of the device shown in FIG. 1, with the cover removed.

FIG. 3 is a schematic diagram of a first exemplary embodiment.

FIG. 4 is a schematic diagram of a second exemplary embodiment.

### DETAILED DESCRIPTION

Various embodiments will now be described in more detail, by way of non-limiting examples, with reference to the drawings accompanying the present disclosure and illustrating certain exemplary embodiments.

The specific structural and functional details disclosed herein are non-limiting examples. The embodiments disclosed here may undergo various modifications and alternative forms. The subject matter of the disclosure may be embodied in many different forms and should not be construed as being limited solely to the embodiments presented herein as illustrative examples. It should be understood that there is no intention to limit the embodiments to the particular forms described in the remainder of this document.

In the following description, identical, similar or analogous elements will be referred to by the same reference numbers. The block diagrams, flowcharts and message sequence diagrams in the figures shows the architecture, functionalities and operation of systems, apparatuses, methods and computer program products according to one or more exemplary embodiments. Each block of a block diagram or each step of a flowchart may represent a module or a portion of software code comprising instructions for implementing one or more functions. According to certain implementations, the order of the blocks or the steps may be changed, or else the corresponding functions may be implemented in parallel. The method blocks or steps may be implemented using circuits, software or a combination of circuits and software, in a centralized or distributed manner, for all or part of the blocks or steps. The described systems, devices, processes and methods may be modified or subjected to additions and/or deletions while remaining within the scope of the present disclosure. For example, the components of a device or system may be integrated or separated. Likewise, the features disclosed may be implemented using more or fewer components or steps, or even with other components or by means of other steps. Any suitable data-processing system can be used for the implementation. An appropriate data-processing system or device comprises for example a combination of software code and circuits, such as a processor, controller or other circuit suitable for executing the software code. When the software code is executed, the processor or controller prompts the system or apparatus to implement all or part of the functionalities of the blocks and/or steps of the processes or methods according to the exemplary embodiments. The software code can be stored in non-volatile memory or on a non-volatile storage medium (USB key, memory card or other medium) that can be read directly or via a suitable interface by the processor or controller.

The present disclosure applies to any device with a housing comprising one or more components arranged behind a cover.

What is meant by “cover” is any part intended to provide access to certain components of the device when the cover is removed, and to prevent such access when it is in position on the housing. In the case of an electric meter, this could be - for example - the meter cover, but also a terminal cover.

It should be noted that these exemplary embodiments are not limiting. In particular, components other than those illustrated may be used to implement the functions described, and fewer or additional components can of course be implemented. In addition, the different values given are for clarity of explanation and may also differ.

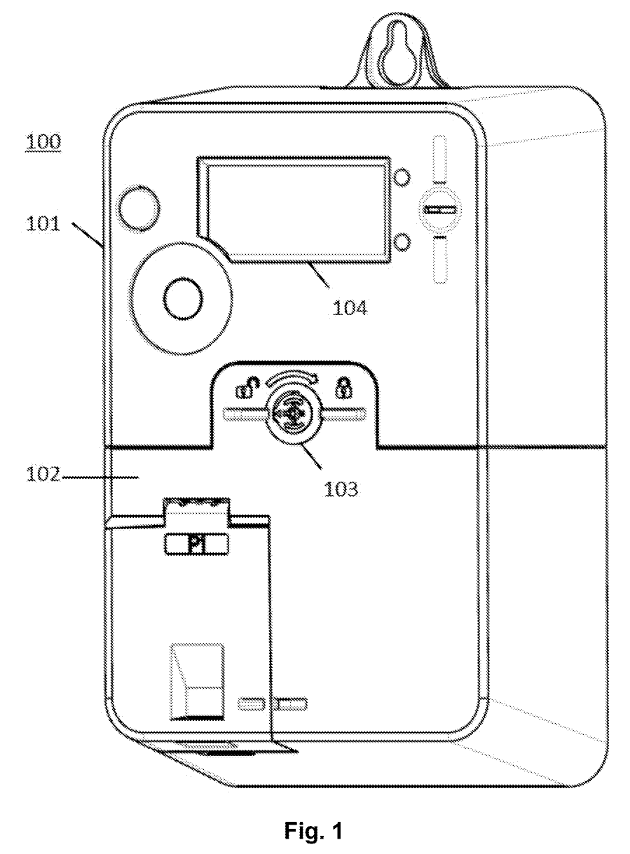

FIG. 1 is a non-limiting example of a device 100, in this case an electric meter. The device illustrated comprises a housing 101 and a cover 102 positioned on the casing in order to prevent access to the electrical terminals of the meter. In the example shown, the cover 102 is mechanically locked to the housing 100 by means of a locking mechanism 103. The device illustrated comprises other components, such as a display 104. The display can be a touchscreen configured to implement a human-machine interface.

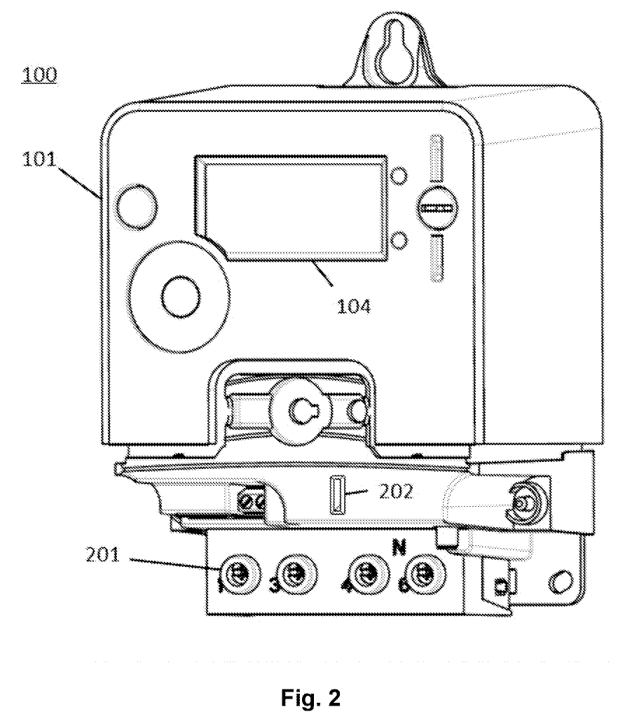

FIG. 2 shows the device shown in FIG. 1 without the cover 102. FIG. 2 shows the electrical terminals 201 of the meter (phases and neutrals), which are not accessible when the cover is in place on the meter, either for safety reasons or to prevent fraud.

According to one or more exemplary embodiments, the device comprises a circuit for detecting opening of the cover. The principle underlying the various embodiments is that a capacitor is charged when the device is powered up. Discharging of this capacitor is triggered by closing a discharge circuit when the cover is opened. Discharging takes place through a fuse. The capacitor and fuse are designed so that the fuse blows as the capacitor is discharged.

According to one embodiment, the capacitor is typically charged after the device has been powered up for the first time, following its installation in its place of operation, since it is - generally - from the time of installation that it is sought to detect any fraud.

According to one embodiment, the discharge circuit can be closed by means of a switch held open by part of the cover when the cover is in the closed position on the housing in order to prevent access to the components, the switch being configured to close when the cover is no longer in the closed position on the housing.

The state - conductive or non-conductive - of the fuse is readily detectable and can give rise to a warning at the appropriate moment.

According to one embodiment, the state of the fuse is determined by a processor from the voltage at one terminal of the fuse.

The capacitor is not used to power an active circuit which would consume the stored energy. This makes it possible to use a capacitor with a relatively low capacitance (e.g. 10 µF), and therefore low cost, and for it to keep its charge for a very long time.

The switch and fuse are positioned in such a way as to restrict the possibility of tampering by an unauthorized person. For example, to prevent an attempt to hold the switch open, or to short-circuit (or where applicable replace) the fuse. For example, the switch and fuse can be placed on a printed circuit board located in a closed compartment of the housing 101 and separated from the portion of this housing that is accessible when the cover is open by suitable walls, an opening being made in a wall of the compartment in order to allow a projecting member of the cover to reach the switch when the cover is closed.

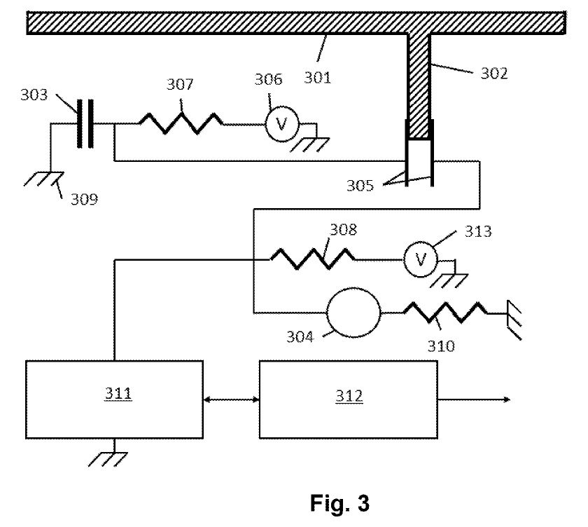

FIG. 3 is a diagram of a first exemplary embodiment of a circuit for detecting opening of the cover.

In the example illustrated, the cover is referenced 301. When the cover is in the closed position on the housing, the cover breaks the continuity of a circuit configured to discharge a capacitor 303 through a fuse 304.

According to one embodiment, one possible implementation consists in providing the cover with a projecting member 302, such as a spike, which moves two elastic metal strips 305 apart when the cover is in the closed position on the housing. The spike is made of a non-conductive material, for example the same insulating material as the cover. The strips and projecting member thus form a switch. The strips are configured to make electrical contact in the absence of the projecting member. They connect a first terminal of the capacitor 303 (in this case the positive terminal) and a first terminal of the fuse 304. When electrical continuity between the strips is restored, the capacitor, if charged, discharges through the fuse. Other embodiments of the switch may be considered, as long as the switch is open when the cover is in the closed position on the housing and closed when the cover is open.

According to one embodiment, the capacitor charging circuit comprises a voltage source 306 connected to the first terminal of the capacitor via a resistor 307. The second (negative) terminal of the capacitor 303 is connected to ground 309. The voltage source 306 is only active when the device 100 is powered up. In principle, he device is powered up after installation and once the cover has been closed. This is when the capacitor becomes charged. The value of the resistor 307 is chosen to limit the charging current of the capacitor 303. An example of the value of this resistor 307 is 100 kΩ. The voltage source 306 has, for example, a voltage of 3.3 V.

According to the exemplary embodiment shown in FIG. 3, the state (conductive or non-conductive) of the fuse is determined by a processor, for example the microcontroller 311, from the voltage at the first terminal of the fuse.

According to one possible implementation, a resistor 308 is connected on the one hand to a voltage source 313 and on the other hand to the first terminal of the fuse. The second terminal of the fuse is connected to ground via a resistor 310. The resistor 310 is intended to force the first terminal of the fuse to zero voltage when the fuse is conducting. When the fuse is no longer conducting, the voltage at the first terminal of the fuse is determined by the voltage source 313. The value of the resistor 308 is chosen to be very large so as to reduce the current that can flow from the source 313 to ground through the fuse and then the resistor 310 when the fuse is conducting. The value of the resistor 310 is chosen to be low, in particular in order to allow the fuse to blow when the capacitor discharges. The resistor 308 has, for example, a value of 100 kΩ and the resistor 310 has, for example, a value of 10 Ω. The high ratio between the two resistors 308 and 310 biases the first terminal of the fuse to ground when the fuse is conducting. The voltage source 313 has, for example, a voltage of 3.3 V.

The capacitor 303 is, for example, a 10 µF ± 20%/10 V multilayer capacitor.

The fuse 304, for example, is a screen-printed fuse designed to blow with certainty at 330 mA and not to blow with certainty at 33 µA. To ensure that it blows as the capacitor is discharged, a blow threshold of 200 mA < 1 ms, for example, can be selected. It is possible to provide a special copper track at least 10 mm long, 35 µm thick and 100 µm wide. Another example of a fuse is an ultra-rapid fuse (FF fuse) designed to blow at 200 mA < 1 ms. Other types of fuse may be considered by a person skilled in the art.

According to the example shown in FIG. 3, the device optionally also comprises a communication interface 312. This modem is, for example, and without limitation, a CPL modem, or an RF modem, or a Wi-Fi wireless interface, or a cellular network interface.

According to one exemplary embodiment, the operation of the device shown in FIG. 3 can comprise the following steps:

a) On leaving the factory, the capacitor 303 is in the discharged state. For example, the strips 305 are in contact, with the cover 301 not in place. The high ratio between the resistors 307 and 310 means that the level of charge of the capacitor 303 is negligible and practically equal to 0 V.

b) The capacitor 307 will be charged when the device is first powered up, after installation and closure of the cover (in this case, closure of the cover or terminal cover). The member integral with the cover is inserted between the two strips, which are then no longer in contact.

c) The first terminal of the fuse, which is conductive at this stage, is biased low (zero voltage), given the high ratio between the resistors 308 and 310. The processor 311 detects the low level and notes that the cover has not been opened.

d) When the cover is opened, the capacitor discharges through the fuse.

e) The fuse blows and becomes non-conductive. The voltage at the first terminal of the fuse is then high (via the voltage source 313).

f) The processor 311 detects the high level and consequently the opening of the cover.

g) The processor 311 can trigger one or more actions following detection of opening of the cover.

In principle, the device will have been powered down before opening the cover. The processor 311 is then no longer powered. When the device is powered up again, the processor 311 can detect that the cover has been opened, even if it has since been closed again.

According to one embodiment, if the processor detects opening of the cover, one or more of the following actions are triggered:

- Transmission of an alert message via the communication interface 312. For example, the transmission can be sent to the electricity grid operator.

- The opening of the shut-off device of the meter in order to stop all supply of power to the customer via the meter.

Preferably, the interrupting means and the member integral with the cover are configured so that it is not possible to access the interrupting means if the cover is removed before the interrupting means have triggered discharging of the capacitor.

According to one non-limiting exemplary embodiment, this can be achieved, for example, by placing the interrupting means behind an opening or passageway made in an internal wall of the housing, as shown in FIG. 2 (reference 202), in which the member integral with the cover is positioned so that the integral member always prevents access to this opening when the cover is being removed, even though the member will already have been moved sufficiently to trigger discharging of the capacitor. According to another non-limiting exemplary embodiment, it is also possible to simply place the interrupting means close to the internal wall of the cover. In a further exemplary embodiment which can be combined with the above, the interrupting means and the integral member are arranged so that even very brief removal of the cover triggers discharging of the capacitor.

According to one variant, the device comprises an additional discharge circuit for discharging the capacitor 303. The purpose of the additional discharge circuit is to allow the capacitor to be discharged without this discharge taking place through the fuse. This allows the cover to be opened without the fuse blowing, e.g. for maintenance purposes.

One non-limiting exemplary implementation of this variant is to provide a controllable switch for shorting the capacitor 303.

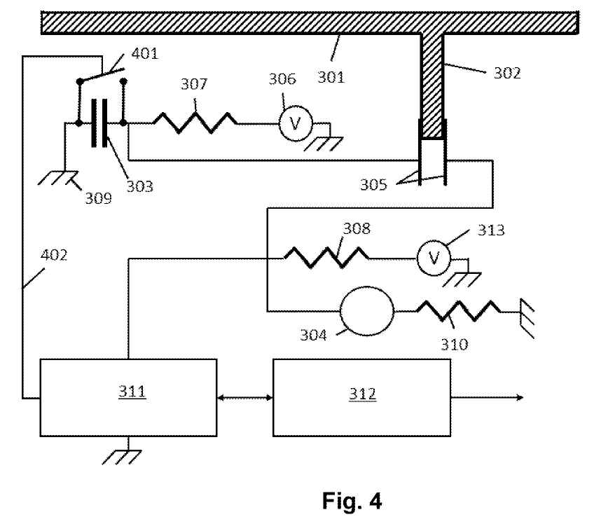

FIG. 4 uses the elements of FIG. 3, and also comprises a switch 401 that connects the two terminals of the capacitor 303 when it is closed. In the example shown, the switch is controlled by a control signal 402 generated by the processor 311. Depending on the implementation, the control signal may be generated in response to an action on the local human-machine interface (e.g. entering a secret code) or in response to receiving a command via the communication interface, e.g. a command from the electricity grid operator.

According to one exemplary embodiment, the operation of the device shown in FIG. 4 can comprise the following steps:

a) When the cover is to be opened, the switch 401 is closed beforehand by the processor 311 generating a close command signal.

b) The capacitor 303 is discharged.

c) The device 100 is powered down. The switch 401 is designed to open automatically in this case.

d) The cover 302 can then be opened.

e) The fuse 308 remains intact.

f) Once the one or more operations have been completed, the cover 302 is closed again.

g) The device 100 is powered up again.

h) The processor 311 detects that the fuse is intact.

i) The capacitor 303 is recharged.

j) The device is again protected against unauthorized opening of the cover.

The switch 401 is - for example - implemented using a MOSFET.

In the examples shown in FIGS. 3 and 4, the device 100 comprises a processor. Some meters comprise multiple processors – for example, an application processor and a metrology processor. Either can perform the function of the processor 311.

An additional advantage of the exemplary embodiments shown is that an installer does not necessarily have to be familiar with the operation of the device. Indeed, installation is the same as for a conventional meter.

In the examples above, the example of an electric meter has been considered. However, the device 100 can be any other type of meter (gas, water, etc.) or any device comprising a housing fitted with an opening cover and for which opening is to be detected.

In one embodiment, opening detection is implemented for multiple elements of a device. Advantageously, a single fuse is used, and multiple switches placed in parallel, one for each element whose opening is to be detected.

By way of non-limiting example, in the case of an electric meter, the opening of both the main cover and the terminal cover can be detected independently. According to one possible implementation, two pairs of strips are placed in parallel, and a single fuse is used. The first pair of strips is moved apart by putting the terminal cover in place, and the second by putting the main cover in place. Opening either of the two members will cause the fuse 304 to blow when the terminal cover or main cover is opened without power if the capacitor 303 is charged.

List of reference signs

100 – Device

101 – Housing

102 – Cover

103 – Lock

104 – Display

201 – Electrical terminals

202 – Opening

301 – Cover

302 – Projecting member

303 – Capacitor

304 – Fuse

305 – Strips

306 – Voltage source

307 – Resistor

308 – Resistor

309 – Ground

310 – Resistor

311 – Processor

312 – Communication interface

313 – Voltage source

401 – Switch

402 – Control signal

1. A device comprising:
a housing comprising components;
a cover configured to be positioned on the housing in order to restrict access to the components when the cover is in a closed position;
a capacitor and a fuse, the capacitor and fuse being dimensioned so that the fuse blows when the capacitor discharges through the fuse;
a capacitor charging circuit configured to charge the capacitor when the device is powered up;
a discharge circuit for discharging the capacitor through the fuse, said discharge circuit comprising a first switch cooperating with a part integral with the cover in order to:
prevent the discharging of the capacitor when the cover is in the closed position; and
allow the capacitor to discharge through the fuse when the cover is in an open position.

2. The device as claimed in claim 1, wherein the discharge circuit is configured to electrically connect the capacitor and the fuse through the first switch, the first switch comprising conductive parts configured to be in electrical contact when the cover is in the open position and to be moved apart by the part integral with the cover when the cover is in the closed position, thereby breaking the electrical contact between the conductive parts.

3. The device as claimed in claim 2, wherein the conductive parts comprise two metal strips.

4. The device as claimed in claim 1, wherein the part integral with the cover is a projecting member integral with the cover.

5. The device as claimed in claim 1, wherein the capacitor charging circuit comprises a voltage source connected to a first terminal of the capacitor through a resistor, a second terminal of the capacitor being connected to ground, the voltage source being configured to provide a voltage for charging the capacitor when the device is powered up.

6. The device as claimed in claim 1, wherein the capacitor is in a discharged state prior to the first time the device is powered up.

7. The device as claimed in claim 1, comprising a second switch controlled by a control signal, the second switch being configured to allow the capacitor to be discharged other than via the fuse.

8. The device as claimed in claim 7, wherein the second switch is configured to short-circuit the capacitor in response to the control signal.

9. The device as claimed in claim 7, comprising a processor configured to generate the control signal under the control of an authorized user.

10. The device as claimed in claim 1, the device being an electric meter and the components comprising electrical terminals of the meter.

11. The device as claimed in claim 1, comprising a processor configured to determine whether or not the fuse has blown and, if so, to generate an alert signal.

12. The device as claimed in claim 1, wherein the fuse is a screen-printed fuse screen-printed on a printed circuit board of the device.
______________________
